(19) United States
(12) Patent Application Publication
(10) Pub. No.: US 2026/0277112 A1
(43) Pub. Date: Sep. 17, 2026

(54) STRUCTURE AND METHOD FOR SURFACE PLASMON LITHOGRAPHY IMAGING, AND COMPUTER-READABLE MEDIUM

(71) Applicant: INSTITUTE OF MICROELECTRONICS, CHINESE ACADEMY OF SCIENCES, Beijing (CN)

(72) Inventors: Dinghai Rui, Beijing (CN); Libin Zhang, Beijing (CN); Yayi Wei, Beijing (CN); Yajuan Su, Beijing (CN)

(21) Appl. No.: 19/371,949

(22) Filed: Oct. 28, 2025

(30) Foreign Application Priority Data
Mar. 12, 2025 (CN) 202510291891.9

(51) Int. Cl. G03F 7/00; G03F 1/48; G03F 1/52; G03F 1/82

(52) U.S. Cl. CPC G03F 7/70425; G03F 1/48; G03F 1/52; G03F 1/82; G03F 7/70125

(57) ABSTRACT

A structure and method for surface plasmon lithography imaging, and a computer-readable medium are provided. The structure includes: a reflective layer, a photoresist layer, a first resonant cavity structure and a mask layer. The reflective layer is arranged at a side of a to-be-etched structure. The photoresist layer is arranged at a side of the reflective layer away from the to-be-etched structure. The first resonant cavity structure is arranged at a side of the photoresist layer away from the to-be-etched structure. The mask layer is arranged at a side of the first resonant cavity structure away from the to-be-etched structure. By arranging the first resonant cavity structure between the mask layer and the photoresist layer in the structure for surface plasmon lithography imaging, a localization effect of the optical field is enhanced, thereby further breaking the diffraction limit, optimizing imaging performance, and improving resolution.

### CROSS-REFERENCE TO RELATED APPLICATIONS

The present application claims priority to Chinese Patent Application No. 202510291891.9, titled “STRUCTURE AND METHOD FOR SURFACE PLASMON LITHOGRAPHY IMAGING, AND COMPUTER-READABLE MEDIUM,” filed on Mar. 12, 2025 with the China National Intellectual Property Administration, which is incorporated herein by reference in its entirety.

### FIELD

The present disclosure relates to the field of semiconductors, and in particular to a structure and a method for surface plasmon lithography imaging, and a computer-readable medium.

### BACKGROUND

With the development of semiconductor-related technologies, the lithography technology, which is one of critical technologies in the fabrication of semiconductor devices, has undergone rapid advancement. Conventional optical lithography technologies rely on optical imaging principles, where a light source illuminates a mask and projects a mask pattern onto a substrate coated with a photoresist, thereby replicating and transferring the mask pattern. However, as integrated circuits continue to evolve toward a higher density and smaller dimensions, the conventional lithography technologies face severe resolution limitations and are unable to meet the requirements for micrometer-scale or even nanometer-scale fabrication. The conventional optical lithography technologies primarily include deep ultraviolet lithography (DUVL) and extreme ultraviolet lithography (EUVL).

A surface plasmon lithography technology, as a complementary technology to mainstream lithography technologies, differs significantly from the traditional optical lithography technology. In the surface plasmon lithography technology, since an evanescent near-field imaging carrying high-frequency information is utilized, the diffraction limit inherent in conventional lithography is overcome.

How to further break through the diffraction limit and enhance the resolution via the surface plasmon lithography technology remains an issue to be addressed.

### SUMMARY

In view of this, the objective of the present disclosure is to provide a structure and a method for surface plasmon lithography imaging, and a computer-readable medium, so as to further break the diffraction limit and enhance the resolution via the structure for surface plasmon lithography imaging.

Technical solutions provided to achieve the forgoing objective according to the present disclosure are described below.

A structure for surface plasmon lithography imaging is provided according to the present disclosure, and the structure includes: a reflective layer arranged at a side of a to-be-etched structure; a photoresist layer arranged at a side of the reflective layer away from the to-be-etched structure; a first resonant cavity structure arranged at a side of the photoresist layer away from the to-be-etched structure; and a mask layer arranged at a side of the first resonant cavity structure away from the to-be-etched structure.

In an embodiment, the first resonant cavity structure includes a first multilayer structure, the first multilayer structure includes a first metal layer and a first dielectric layer, and the first dielectric layer is arranged at a side of the first metal layer away from the to-be-etched structure.

In an embodiment, a second resonant cavity structure is arranged between the reflective layer and the to-be-etched structure.

In an embodiment, the second resonant cavity structure includes at least one second multilayer structure, each of the at least one second multilayer structure includes a second metal layer and a second dielectric layer, and the second dielectric layer is arranged at a side of the second metal layer away from the to-be-etched structure.

In an embodiment, a thickness of the second resonant cavity structure is greater than a thickness of the first resonant cavity structure.

In an embodiment, a thickness of the first metal layer ranges from 5 nm to 50 nm, and a thickness of the first dielectric layer ranges from 1 nm to 50 nm.

In an embodiment, when a mask pattern of the mask layer is fixed, a pitch of a pattern formed on the to-be-etched structure during etching is regulated through regulating a thickness of the photoresist layer.

In an embodiment, a transparent substrate is arranged at a side of the mask layer away from the to-be-etched structure.

A method for surface plasmon lithography imaging is further provided according to the present disclosure, and the method includes:
forming a reflective layer at a side of a to-be-etched structure;
forming a photoresist layer at a side of the reflective layer away from the to-be-etched structure;
forming a first resonant cavity structure at a side of the photoresist layer away from the to-be-etched structure; and
forming a mask layer at a side of the first resonant cavity structure away from the to-be-etched structure, where the reflective layer, the photoresist layer, the first resonant cavity structure, and the mask layer form a structure for surface plasmon lithography imaging;
illuminating the structure for surface plasmon lithography imaging in a direction from the mask layer toward the to-be-etched structure, to transfer a mask pattern of the mask layer to the photoresist layer to form a patterned photoresist layer; and
etching the to-be-etched structure by using the patterned photoresist layer.

A computer-readable storage medium is provided according to an embodiment of the present disclosure. The computer-readable storage medium includes instructions. The instructions, when being executed on a computer, causes the computer to perform the method according to the embodiments described above.

A structure for surface plasmon lithography imaging is provided according to the present disclosure. The structure includes: a reflective layer, a photoresist layer, a first resonant cavity structure and a mask layer. The reflective layer is arranged at a side of a to-be-etched structure. The photoresist layer is arranged at a side of the reflective layer away from the to-be-etched structure. The first resonant cavity structure is arranged at a side of the photoresist layer away from the to-be-etched structure. The mask layer is arranged at a side of the first resonant cavity structure away from the to-be-etched structure. By arranging the first resonant cavity structure between the mask layer and the photoresist layer in the structure for surface plasmon lithography imaging, a localization effect of the optical field is enhanced, thereby further breaking the diffraction limit, optimizing imaging performance, and improving resolution.

### BRIEF DESCRIPTION OF THE DRAWINGS

In order to more clearly describe technical solutions in embodiments of the present disclosure or in the conventional technology, drawings to be used in the description of the embodiments of the present disclosure or the conventional technology are briefly described hereinafter. Apparently, the drawings described below illustrate merely some embodiments of the present disclosure, and those skilled in the art may obtain other drawings based on the provided drawings without any creative effort.

FIG. 1 is a schematic structural diagram of a structure for surface plasmon lithography imaging according to an embodiment of the present disclosure;

FIG. 2 is a schematic structural diagram of a structure for surface plasmon lithography imaging according to another embodiment of the present disclosure;

FIG. 3 is a schematic diagram illustrating an imaging result obtained through a rigorous coupled-wave analysis algorithm at a wavelength of 436 nm, according to an embodiment of the present disclosure;

FIG. 4 is a schematic diagram illustrating an imaging result obtained through a finite element method at a wavelength of 436 nm, according to an embodiment of the present disclosure;

FIG. 5 is a schematic diagram illustrating an imaging result obtained through a rigorous coupled-wave analysis algorithm at a wavelength of 532 nm, according to an embodiment of the present disclosure;

FIG. 6 is a schematic diagram illustrating an imaging result obtained through a finite element method at a wavelength of 532 nm, according to an embodiment of the present disclosure;

FIG. 7 is a schematic diagram illustrating an imaging result obtained through a rigorous coupled-wave analysis algorithm at a wavelength of 633 nm, according to an embodiment of the present disclosure;

FIG. 8 is a schematic diagram illustrating an imaging result obtained through a finite element method at a wavelength of 633 nm, according to an embodiment of the present disclosure;

FIG. 9 is a schematic diagram illustrating an imaging result with a wavelength of 436 nm and a thickness of a photoresist layer being 25 nm, according to an embodiment of the present disclosure;

FIG. 10 is a schematic diagram illustrating an imaging result with a wavelength of 436 nm and a thickness of a photoresist layer being 40 nm, according to an embodiment of the present disclosure;

FIG. 11 is a schematic diagram illustrating a light intensity distribution of a photoresist layer at a wavelength of 532 nm, according to an embodiment of the present disclosure;

FIG. 12 is a schematic diagram illustrating a light intensity distribution of a photoresist layer at a wavelength of 633 nm, according to an embodiment of the present disclosure; and

FIG. 13 is a flowchart of a method for surface plasmon lithography imaging according to an embodiment of the present disclosure.

### DETAILED DESCRIPTION

In order to make the above objectives, features, and advantages of the present disclosure more apparent and easier to understand, embodiments of the present disclosure are described in detail below in conjunction with the drawings.

Various details are set forth in following description to facilitate a full understanding of the present disclosure. The present disclosure may be implemented in a manner different from those described herein, and those skilled in the art may perform analogous promotion without departing from the connotation of the present disclosure. Therefore, the present disclosure is not limited by the embodiments disclosed hereinafter.

The present disclosure is described in detail in conjunction with schematic diagrams. To facilitate description in describing embodiments of the present disclosure in detail, a cross-sectional view showing a structure of a device is partially enlarged, not on a general scale. The schematic diagrams are merely exemplary, which are not intended to limit the protection scope of present disclosure. In addition, three-dimensional spatial dimensions of length, width, and depth should be included in practice.

The lithography technology constitutes one of the indispensable core technologies in modern micro/nano fabrication, and is extensively applied in the manufacturing of integrated circuits, optoelectronic devices, and nanotechnology. Conventional optical lithography technologies rely on optical imaging principles, where a light source illuminates a mask and projects a mask pattern onto a substrate coated with a photoresist, thereby replicating and transferring the mask pattern. However, as integrated circuits continue to evolve toward a higher density and smaller dimensions, the conventional lithography technologies face severe resolution limitations and are unable to meet the requirements for micrometer-scale or even nanometer-scale fabrication.

According to the principle of optical diffraction, the resolution of conventional optical lithography is limited by a diffraction limit, which is generally expressed by the following equation.

$${R}_{litho} = {k}_{1} \frac{λ}{NA}$$

According to the above equation, for deep ultraviolet lithography, a resolution of approximately 38 nm (with a pitch of 76 nm) can be achieved via the immersion lithography technology (utilizing a light source with a wavelength of 193 nm), while the limit of the resolution achievable in commercial mass production is 40 nm (with a pitch of 80 nm). That is, the resolution of the immersion lithography technology approaches one-fifth of the wavelength. However, such a resolution is still insufficient to meet the manufacturing requirements of future nano-scale or even subnano-scale electronic and optoelectronic devices, and particularly in the fabrication process of an integrated circuit having a smaller dimension and a higher integration density.

Currently, the surface plasmon lithography (SPL) technology is an emerging nano-scale optical technology. By utilizing the localized field enhancement effect of surface plasmons, more precise optical manipulation are enabled at a sub-wavelength scale. Therefore, some studies propose to exploit the negative refraction characteristic of materials to achieve wavelength-scale or even smaller resolution, with the potential to reduce the lithographic resolution to one-tenth of the wavelength or less. However, these technologies have not been applied in the lithography technology.

How to further break through the diffraction limit and enhance the resolution via the surface plasmon lithography technology remains an issue to be addressed.

On this basis, a structure for surface plasmon lithography imaging is provided according to the present disclosure. The structure includes: a reflective layer, a photoresist layer, a first resonant cavity structure and a mask layer. The reflective layer is arranged at a side of a to-be-etched structure, the photoresist layer is arranged at a side of the reflective layer away from the to-be-etched structure, the first resonant cavity structure is arranged at a side of the photoresist layer away from the to-be-etched structure, and the mask layer is arranged at a side of the first resonant cavity structure away from the to-be-etched structure. By configuring the first resonant cavity structure between the mask layer and the photoresist layer in the structure for surface plasmon lithography imaging, a localization effect of the optical field is enhanced, thereby further breaking the diffraction limit, optimizing imaging performance, and improving the resolution.

For better understanding technical solutions and technical effects of the present disclosure, embodiments are described in detail in conjunction with the drawings hereinafter.

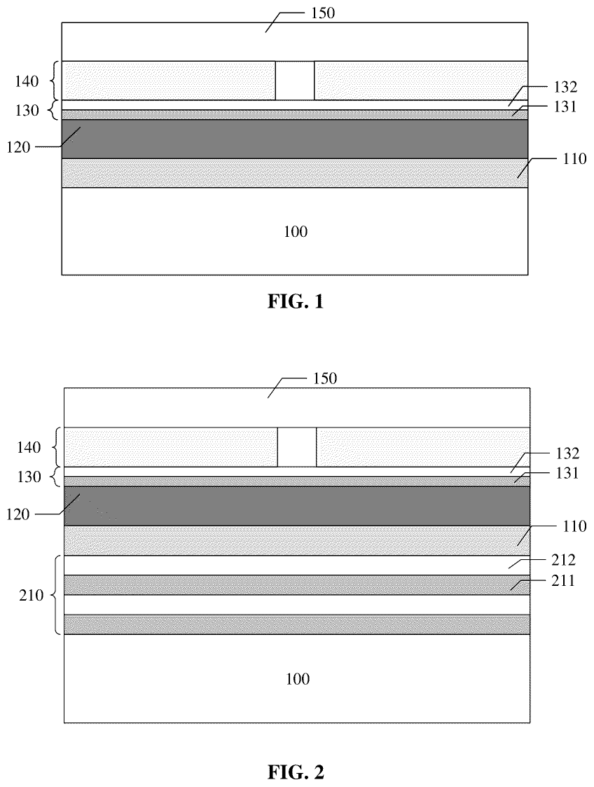

Reference is made to FIG. 1, which is a schematic structural diagram of a structure for surface plasmon lithography imaging according to an embodiment of the present disclosure. The structure for surface plasmon lithography imaging includes: a reflective layer 110, a photoresist layer 120, a first resonant cavity structure 130 and a mask layer 140.

In the embodiment of the present disclosure, the reflective layer 110 is arranged at a side of a to-be-etched structure 100. That is, the reflective layer 110 covers the to-be-etched structure 100. The to-be-etched structure 100 may be a single film layer, or a semiconductor structure including multiple film layers which is fabricated through multiple manufacturing processes.

As an example, the to-be-etched structure 100 is a wafer, and the wafer is made of silicon (Si), germanium (Ge), gallium arsenide (GaAs), quartz glass, sapphire glass, or other materials suitable for microelectronic fabrication.

The reflective layer 110 serves to enhance the adhesion of the photoresist layer 120 arranged thereon, and provides conductivity, reflectivity, or other optical properties during the lithography and development process, so as to improve imaging performance and pattern transfer precision. The reflective layer 110 may be made of a metallic material, such as silver.

In the embodiment of the present disclosure, the photoresist layer 120 is arranged at a side of the reflective layer 110 away from the to-be-etched structure 100. That is, the photoresist layer 120 covers the reflective layer 110. The photoresist layer 120 is for patterning, so as to transfer the mask pattern. The photoresist includes a positive photoresist or a negative photoresist. After exposure for the positive photoresist, the positive photoresist within the exposed regions are removed during development, while the positive photoresist within the unexposed regions are retained. In contrast, after exposure for the negative photoresist, the negative photoresist within the exposed regions are retained, and the negative photoresist within the unexposed regions are removed during development. A photoresist used in the photoresist layer 120 is selected based on the photosensitivity, resolution, viscosity of the photoresist, and an etch selectivity of the photoresist relative to the material of the to-be-etched structure 100.

In the embodiment of the present disclosure, a first resonant cavity structure 130 is arranged at a side of the photoresist layer 120 away from the to-be-etched structure 100. That is, the first resonant cavity structure 130 covers the photoresist layer 120. The first resonant cavity structure 130 is configured to regulate the reflection, transmission, and enhancement of light, and exhibits a resonant cavity effect.

In the embodiment of the present disclosure, a mask layer 140 is arranged at a side of the first resonant cavity structure 130 away from the to-be-etched structure 100. That is, the mask layer 140 covers the first resonant cavity structure 130. The mask layer 140 refers to a mask structure for defining and transferring micro/nano patterns during the lithography process. The mask layer 140 precisely transfers a designed pattern to the photoresist or other photosensitive materials through exposure and development, thereby forming a desired microstructure. For the excitation of plasma, the mask layer 140 is typically formed by a transparent material and a metallic pattern. The metallic pattern is fabricated on the mask substrate through lithography, where the transparent material is for light transmission and the metallic pattern is for light blocking.

As an example, with reference to FIG. 1 or FIG. 2, the material of the metallic pattern of the mask layer 140 is silver, and the transparent material is air. The mask pattern of the mask layer 140 includes stripes configured with one-dimensional periodic variation.

As described above, by configuring the first resonant cavity structure 130 between the mask layer 140 and the photoresist layer 120 in the structure for surface plasmon lithography imaging, a localization effect of the optical field is enhanced through the first resonant cavity structure 130, thereby further breaking the diffraction limit, optimizing imaging performance, and improving resolution.

In an embodiment of the present disclosure, the first resonant cavity structure 130 includes a first multilayer structure. The first multilayer structure includes a first metal layer 131 and a first dielectric layer 132, and the first dielectric layer 132 is arranged at a side of the first metal layer 131 away from the to-be-etched structure 100. That is, the first dielectric layer 132 covers the first metal layer 131, as shown in FIG. 1 and FIG. 2.

The optical performance of the resonant cavity is optimized by configuring the first multilayer structure including the first metal layer 131 and the first dielectric layer 132, so as to meet design requirements. The first metal layer 131 is configured to provide reflectivity and conductivity, and the first dielectric layer 132 is configured to regulate the propagation characteristics and wavelength response of light, for example, regulate the propagation, reflection, and transmission characteristics of the light.

In an embodiment, the first metal layer 131 may be made of a metallic material or a material exhibiting a negative refractive index and high reflectivity at the optical wavelength used for imaging, such as silver, aluminum, or gold. The first dielectric layer 132 may be made of air, high-purity water, or other dielectric materials, such as silicon dioxide or silicon nitride.

A thickness of the first metal layer 131 ranges from 5 nm to 50 nm, and a thickness of the first dielectric layer 132 ranges from 1 nm to 50 nm. That is, the resonant cavity effect of the first resonant cavity structure 130 is achieved by configuring the first metal layer 131 and the first dielectric layer 132 with appropriate thicknesses.

The thicknesses, materials, and fabrication methods of the first metal layer 131 and the first dielectric layer 132 may be optimized based on parameters such as the operating wavelength, reflectivity requirement, and resonant frequency of the first resonant cavity structure 130, thereby obtaining an efficient first resonant cavity structure 130.

In an embodiment of the present disclosure, a second resonant cavity structure 210 is arranged between the reflective layer 110 and the to-be-etched structure 100. As shown in FIG. 2, the second resonant cavity structure 210 is arranged opposite to the first resonant cavity structure 130, with the reflective layer 110 and the photoresist layer 120 arranged between the second resonant cavity structure 210 and the first resonant cavity structure 130. Through the cooperation between the first resonant cavity structure 130 and the second resonant cavity structure 210, the optical field is further enhanced and the propagation characteristic of light is controlled, thereby further enhancing the localization effect of the optical field, breaking the diffraction limit, optimizing the imaging performance, and improving the resolution.

In an embodiment of the present disclosure, the second resonant cavity structure 210 includes at least one second multilayer structure. The second multilayer structure includes a second metal layer 211 and a second dielectric layer 212, and the second dielectric layer 212 is arranged at a side of the second metal layer 211 away from the to-be-etched structure 100. That is, the second dielectric layer 212 covers the second metal layer 211, as shown in FIG. 2.

The optical performance of the resonant cavity is optimized by configuring the second multilayer structure including the second metal layer 211 and the second dielectric layer 212, so as to meet design requirements. The second metal layer 211 is configured to provide reflectivity, while the second dielectric layer 212 is configured to regulate the propagation characteristic and wavelength response of light, for example, regulate the propagation, reflection, and transmission characteristics of the light.

In an embodiment, the second metal layer 211 may be made of a metallic material or a material exhibiting a negative refractive index and high reflectivity at the optical wavelength used for imaging, such as silver, aluminum, or gold. The second dielectric layer 212 may be made of dielectric materials, such as silicon dioxide or silicon nitride.

A thickness of the second metal layer 211 ranges from 5 nm to 50 nm, and a thickness of the second dielectric layer 212 ranges from 1 nm to 50 nm. That is, the resonant cavity effect of the second resonant cavity structure 210 is achieved by configuring the second metal layer 211 and the second dielectric layer 212 with appropriate thicknesses.

The thicknesses, materials, and refractive indexes of the second metal layer 211 and the second dielectric layer 212 may be optimized based on parameters such as the operating wavelength, reflectivity requirement, and resonant frequency of the second resonant cavity structure 210, thereby obtaining an efficient second resonant cavity structure 210.

The second resonant cavity structure 210 may include at least one second multilayer structure, and the number the second multilayer structures may be determined based on design requirements of the second resonant cavity structure 210, thereby obtaining an efficient second resonant cavity structure 210.

As an example, as shown in FIG. 2, the second resonant cavity structure 210 includes two second multilayer structures.

In an embodiment of the present disclosure, a thickness of the second resonant cavity structure 210 is greater than a thickness of the first resonant cavity structure 130. The thickness of the second resonant cavity structure 210 is greater than that of the first resonant cavity structure 130. Therefore, at least one second multilayer structure is configured, so as to cooperate with the first resonant cavity structure 130 to enhance the localization effect of the optical field.

In an embodiment of the present disclosure, a transparent substrate 150 is arranged at a side of the mask layer 140 away from the to-be-etched structure 100, that is, the transparent substrate 150 covers the mask layer 140. The transparent substrate 150 serves to protect the mask layer 140 and allow light transmission. The transparent substrate 150 may be made of a material such as quartz or glass.

In an embodiment of the present disclosure, the structure for surface plasmon lithography imaging is illuminated in a direction from the mask layer 140 toward the to-be-etched structure 100, that is, the structure for surface plasmon lithography imaging is illuminated by collimated, normally incident light, so that the mask pattern of the mask layer 140 is transferred to the photoresist layer 120, thereby forming a patterned photoresist layer 120. The to-be-etched structure 100 is then etched by using the patterned photoresist layer 120, such that the mask pattern is ultimately transferred onto the to-be-etched structure 100.

The structure for surface plasmon lithography imaging may be applied to surface plasmon lithography imaging with wavelengths of 436 nm, 532 nm, and 633 nm. A detailed description is provided below.

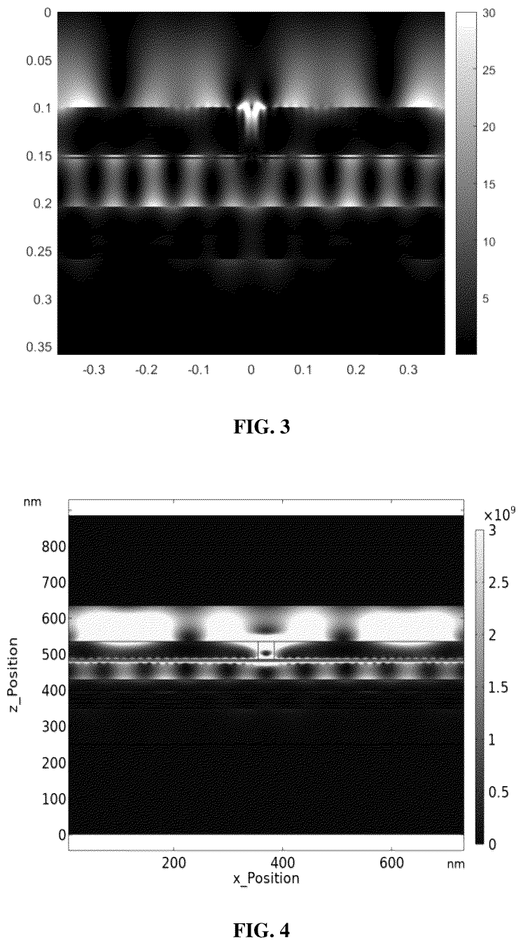

With a wavelength of 436 nm and a pitch of the mask pattern being 740 nm, by using the structure for surface plasmon lithography imaging provided in the embodiment of the present disclosure, a stripe resolution of 32 nm (approximately 1/13.5 of the lithographic wavelength) is achieved. Reference is made to FIG. 3, which illustrates an imaging result obtained through a rigorous coupled-wave analysis (RCWA) algorithm at the wavelength of 436 nm. Reference is made to FIG. 4, which illustrates an imaging result obtained through a finite element method (FEM) at the wavelength of 436 nm.

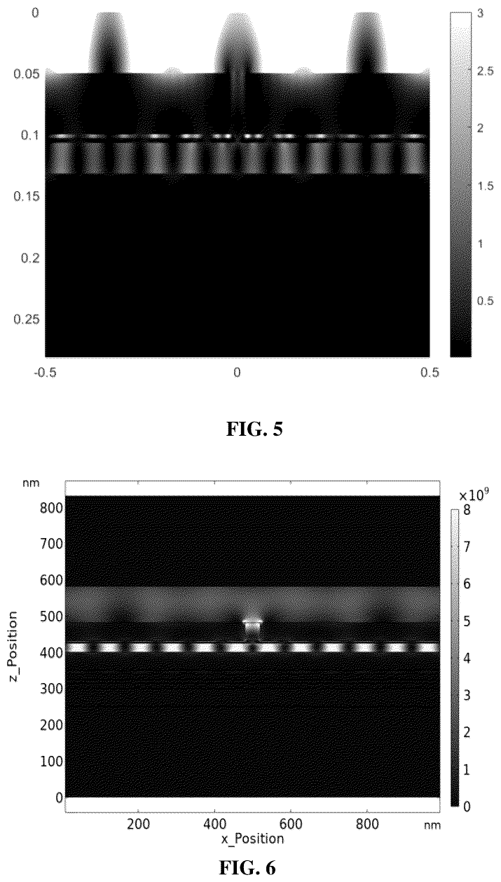

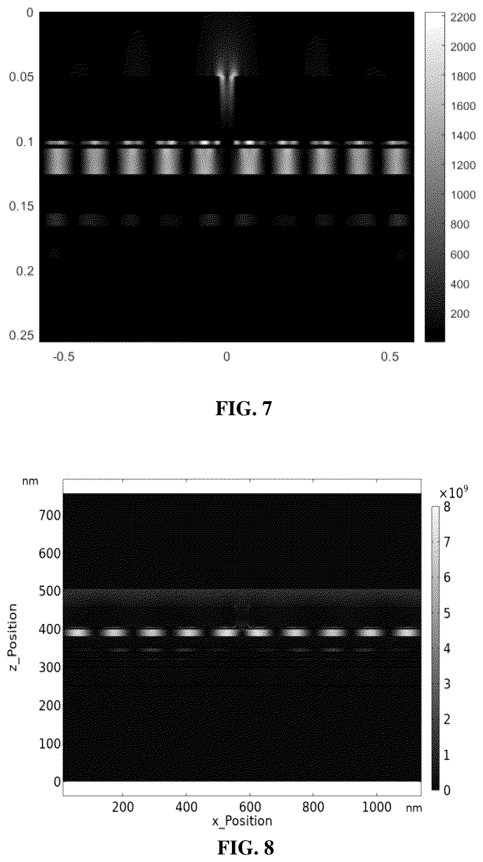

With a wavelength of 532 nm and a pitch of the mask pattern being 1000 nm, by using the structure for surface plasmon lithography imaging provided in the embodiment of the present disclosure, a stripe resolution of 41.6 nm (approximately 1/12.8 of the lithographic wavelength) is achieved. Reference is made to FIG. 5, which illustrates an imaging result obtained through a rigorous coupled-wave analysis algorithm at the wavelength of 532 nm. Reference is made to FIG. 6, which illustrates an imaging result obtained through a finite element method at the wavelength of 532 nm.

With a wavelength of 633 nm and a pitch of the mask pattern being 1152 nm, by using the structure for surface plasmon lithography imaging provided in the embodiment of the present disclosure, a stripe resolution of 28.8 nm (approximately 1/11 of the lithographic wavelength) is achieved. Reference is made to FIG. 7, which illustrates an imaging result obtained through a rigorous coupled-wave analysis algorithm at the wavelength of 633 nm. Reference is made to FIG. 8, which illustrates an imaging result obtained through a finite element method at the wavelength of 633 nm.

It can be seen that, in the structure for surface plasmon lithography imaging provided in the embodiment of the present disclosure, a self-excitation effect is generated and super-resolution imaging is achieved, thereby achieving imaging resolutions far smaller than the lithographic wavelength at 436 nm, 532 nm, and 633 nm.

In an embodiment of the present disclosure, when the mask pattern of the mask layer 140 and the lithographic wavelength are fixed, a pitch of a pattern formed on the to-be-etched structure 100 during etching is regulated through varying a thickness of the photoresist layer 120.

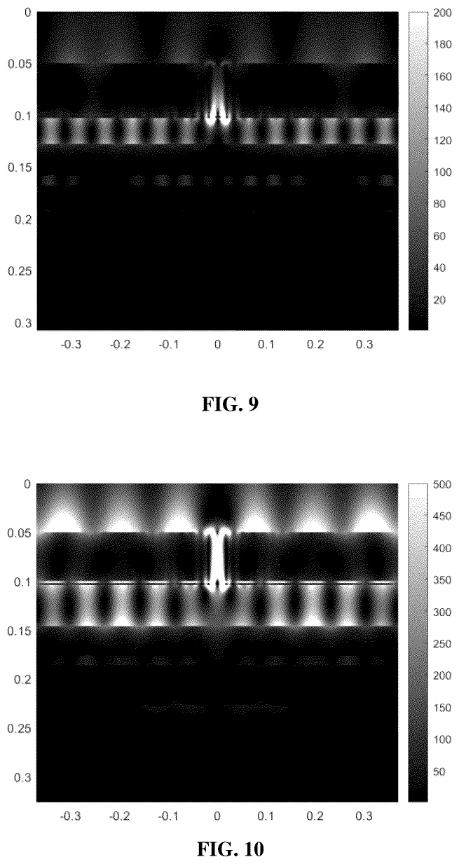

As an example, with a wavelength of 436 nm and a pitch of a mask pattern being 740 nm, stripes with different resolutions are generated by regulated the thickness of the photoresist layer 120. When the thickness of the photoresist layer 120 is 50 nm, the critical dimension (CD) is 32 nm, that is, CD=32 nm, as shown in FIG. 3. When the thickness of the photoresist layer 120 is 25 nm, CD=26.5 nm, as shown in FIG. 9. When the thickness of the photoresist layer 120 is 40 nm, CD=34 nm, as shown in FIG. 10.

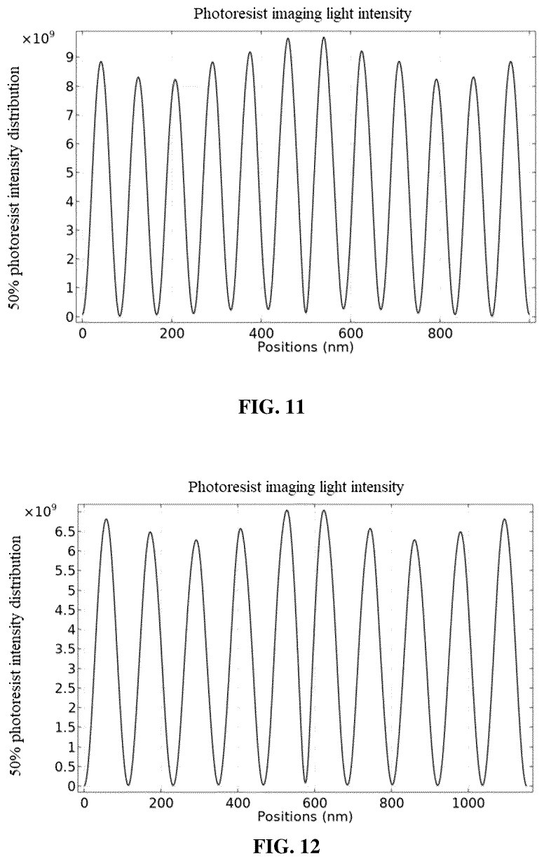

In the embodiment of the present disclosure, imaging using the structure for surface plasmon lithography imaging exhibits a contrast higher than the contrast required by the conventional optical lithography. Reference is made to FIG. 11 and FIG. 12, which illustrate imaging light intensity in the photoresist layer for the exposure performed at a wavelength of 532 nm and 633 nm, respectively. The contrast calculated according to the contrast formula is 0.985 at 532 nm and 0.991 at 633 nm, both of which are significantly higher than a contrast of 0.4 that is required by the conventional optical lithography. This demonstrates that the structure for surface plasmon lithography imaging provided in the embodiment of the present disclosure achieves superior imaging performance.

From the above description, it can be seen that in the structure for surface plasmon lithography imaging provided in the embodiment of the present disclosure, by arranging the first resonant cavity structure 130 and the second resonant cavity structure 210, the imaging resolution is enhanced. For example, at a wavelength of 436 nm, the imaging half-pitch (resolution) is reduced to 7.33% of the wavelength (CD=32 nm), which is far below the resolution limit of the conventional optical imaging, thereby achieving super-resolution imaging. The structure for surface plasmon lithography imaging provided in the present embodiment may further be applied to light sources with various wavelengths. In addition to obtaining super-resolution imaging result at a wavelength of 436 nm, resolutions smaller than one-tenth of the wavelength can be achieved at wavelengths of 532 nm and 633 nm using the structure for surface plasmon lithography imaging provided in the present embodiment, demonstrating its versatility. The pattern obtained through imaging performed using the structure for surface plasmon lithography imaging provided in the present embodiment has a high resolution, a high intensity, and a high contrast. As a result, the quality and precision of lithography are significantly improved. By combining rigorous coupled-wave analysis and finite element methods, the imaging results are analyzed in depth, ensuring the practicality and reliability of the structure for surface plasmon lithography imaging provided in the embodiment of the present disclosure, from both theoretical and experimental perspectives. Imaging via the structure for surface plasmon lithography imaging enables stable operation in practical production environments, with high reproducibility and consistency. In addition, the structure for surface plasmon lithography imaging provided in the present embodiment allows regulation of the pitch of the pattern. For example, by vary the thickness of the photoresist layer, the pitch of the pattern can be flexibly regulated, providing greater design freedom for semiconductor device fabrication processes.

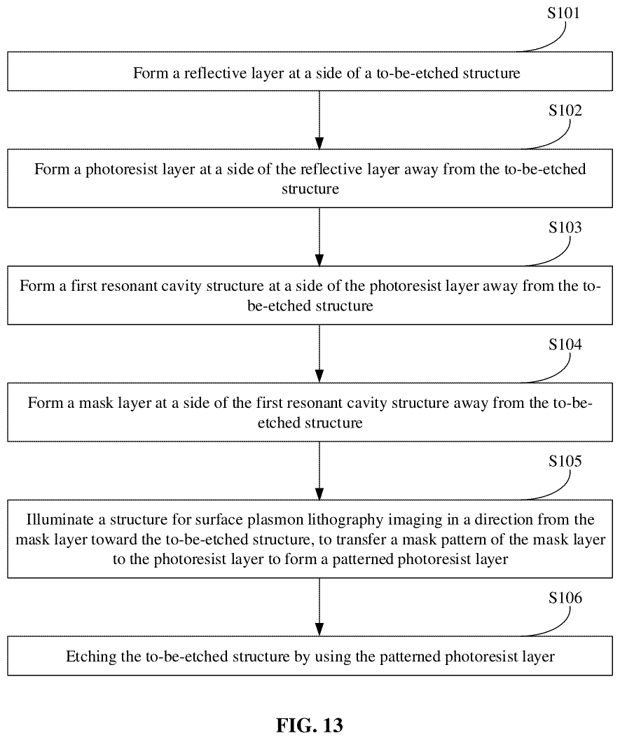

Based on the structure for surface plasmon lithography imaging provided in the above embodiments, a method for surface plasmon lithography imaging is further provided according to the embodiment of the present disclosure. Reference is made to FIG. 13, which is a flowchart of a method for surface plasmon lithography imaging according to an embodiment of the present disclosure. The method for surface plasmon lithography imaging provided according to the embodiment of the present disclosure includes the following steps S101 to S106.

In step S101, a reflective layer is formed at a side of a to-be-etched structure.

In the embodiment of the present disclosure, the reflective layer may be formed at a side of the to-be-etched structure. Specifically, the reflective layer may be fabricated by a deposition process.

In an embodiment of the present disclosure, before the reflective layer is formed, a second resonant cavity structure may be formed at a side of the to-be-etched structure. The second resonant cavity structure includes at least one second multilayer structure. The second multilayer structure includes a second metal layer and a second dielectric layer, and the second dielectric layer is arranged at a side of the second metal layer away from the to-be-etched structure. That is, the second dielectric layer covers the second metal layer.

One second multilayer structure may be formed, the process of the formation includes the follows: a second metal layer of the second multilayer structure is formed, and then a second dielectric layer of the second multilayer structure is formed. The second metal layer may be fabricated by a method such as physical vapor deposition (PVD), sputtering deposition, or electron beam evaporation. The second dielectric layer may be fabricated by a method such as chemical vapor deposition (CVD), atomic layer deposition (ALD), or sputtering.

In step S102, a photoresist layer is formed at a side of the reflective layer away from the to-be-etched structure.

In the embodiment of the present disclosure, after the reflective layer is formed, the photoresist layer may be formed on the side of the reflective layer away from the to-be-etched structure, that is, the photoresist layer is formed on the reflective layer.

In an embodiment, the photoresist layer may be formed by a spin-coating process.

Since the photoresist affects the precision of subsequent mask pattern transfer as well as the quality and resolution of the final imaging pattern, the spin-coating process serves as a critical process in fabricating the structure for surface plasmon lithography imaging.

In step S103, a first resonant cavity structure is formed at a side of the photoresist layer away from the to-be-etched structure.

In the embodiment of the present disclosure, after the photoresist layer is formed, the first resonant cavity structure may be formed on the side of the photoresist layer away from the to-be-etched structure, that is, the first resonant cavity structure is formed on the photoresist layer.

The first resonant cavity structure includes a first multilayer structure, and the first multilayer structure includes a first metal layer and a first dielectric layer. The first dielectric layer is arranged at a side of the first metal layer away from the to-be-etched structure, that is, the first dielectric layer covers the first metal layer.

The first metal layer is formed, and then the first dielectric layer is formed. The first metal layer may be fabricated by a method such as physical vapor deposition (PVD), sputtering deposition, or electron beam evaporation. The first dielectric layer may be fabricated by a method such as chemical vapor deposition (CVD), atomic layer deposition (ALD), or sputtering.

In step S104, a mask layer is formed at a side of the first resonant cavity structure away from the to-be-etched structure.

In the embodiment of the present disclosure, after the first resonant cavity structure is formed, the mask layer may be formed on the side of the first resonant cavity structure away from the to-be-etched structure, that is, the mask layer is formed on the first resonant cavity structure.

In an embodiment, the mask layer is typically formed by a transparent material and a metallic pattern. The metallic pattern is fabricated on the mask substrate through lithography, where the transparent material is for light transmission and the metallic pattern is for light blocking.

After the mask layer is fabricated, a transparent substrate may further be formed on the mask layer. The second resonant cavity structure, the reflective layer, the photoresist layer, the first resonant cavity structure, the mask layer, and the transparent substrate form the structure for surface plasmon lithography imaging.

In step S105, the structure for surface plasmon lithography imaging is illuminated in a direction from the mask layer toward the to-be-etched structure, to transfer a mask pattern of the mask layer to the photoresist layer to form a patterned photoresist layer.

In an embodiment of the present disclosure, the structure for surface plasmon lithography imaging may be illuminated in the direction from the mask layer toward the to-be-etched structure, that is, the structure for surface plasmon lithography imaging is illuminated by collimated, normally incident light, so that the mask pattern of the mask layer is transferred to the photoresist layer, thereby forming a patterned photoresist layer.

In an embodiment, forming the patterned photoresist layer includes operations of exposure and development. The exposure operation in the lithography process involves illuminating the structure for surface plasmon lithography imaging with a collimated, normally incident light source, so as to ensure uniform illumination by the light beam and accurate transfer of the mask pattern. In view of the fact that TM (Transverse Magnetic) waves are more effective for imaging than TE (Transverse Electric) waves, collimated light with TM polarization at wavelengths of 436 nm, 532 nm, and 633 nm may be used for exposure.

The development operation is performed after exposure, where the unexposed portions or the exposed portions in the photoresist layer (depending on the type of the photoresist used) are removed by a developer. The development process involves processing the photoresist layer with a chemical solution (developer), such that the photoresist in the exposed regions is removed, while the photoresist in the unexposed regions is retained, thereby forming a pattern consistent with the mask pattern, that is, forming the patterned photoresist layer.

In step S106, the to-be-etched structure is etched by using the patterned photoresist layer.

In the embodiment of the present disclosure, after the patterned photoresist layer is formed, the to-be-etched structure is etched based on patterned photoresist layer, so that the mask pattern is ultimately transferred onto the to-be-etched structure. In other words, after development is completed, the mask pattern has been transferred onto the photoresist layer, and the process enters the etching stage, in which the thin-film material beneath the photoresist layer is removed through chemical reactions or physical bombardment, thereby transferring the mask pattern to the to-be-etched structure.

Based on the method for surface plasmon lithography imaging provided in the above embodiments, a device for surface plasmon lithography imaging is further provided in the present disclosure. The device for surface plasmon lithography imaging includes: a processor and a memory. The number of the processor may be one or more. In some embodiments of the present disclosure, the processor is connected to the memory via a bus or in other way.

The memory may include a read-only memory and a random access memory, and provide instructions and data to the processor. Part of the memory may further include NVRAM. The memory stores an operating system and operating instructions, executable modules or data structures, or subsets thereof, or extended sets thereof. The operating instructions may include various operating commands for implementing various operations.

The operating system may include various system programs for implementing various basic services and processing hardware-based tasks.

The processor controls operation of a terminal device, and the processor may also be called as CPU.

The method disclosed in the above embodiments of the present disclosure may be applied to a processor or be implemented by the processor. The processor may be an integrated circuit chip with signal processing capability. During an implementation process, steps of the above method may be implemented by an integrated logic circuit in a form of hardware in the processor or through software instructions. The processor may be a general-purpose processor, DSP, ASIC, FPGA or other programmable logic devices, discrete gate or transistor logic devices, and discrete hardware components. The methods, steps and logical block diagrams disclosed in the embodiments of the present disclosure may be implemented or performed. The general-purpose processor may be a microprocessor, or may be any common processors. The steps of the method disclosed in conjunction with the embodiments of the present disclosure may be directly embodied and executed by a hardware decoding processor, or be executed by a combination of a hardware and a software module in the decoding processor. The software module may be in a well-established storage medium in the art such as a random access memory, a flash memory, a read-only memory, a programmable read-only memory, an electrically erasable programmable memory, or a register. The storage medium is in the memory, and the processor reads information in the memory and performs the steps of the above method in combination with the hardware.

A computer-readable storage medium is further provided according to an embodiment of the present disclosure. The computer-readable storage medium is configured to store program codes, and the program codes are used to perform the method according to any one of the above embodiments.

In the context of the present disclosure, the computer-readable medium may be a tangible medium that contains or stores a program for use by, or in conjunction with, an instruction execution system, apparatus, or device. The computer-readable medium may be a computer-readable signal medium or a computer-readable storage medium. The computer-readable medium may include, but is not limited to, an electronic, magnetic, optical, electromagnetic, infrared medium or semiconductor system, apparatus or device, or any proper combination thereof. More specific examples of the computer-readable storage medium may include, one or more wire-based electrical connections, a portable computer disk, a hard disk, a random-access memory (RAM), a read-only memory (ROM), an erasable programmable read-only memory (EPROM or a flash memory), an optical fiber, a portable compact disc read-only memory (CD-ROM), an optical storage device, a magnetic storage device or any suitable combination thereof.

It should be noted that, the computer-readable medium according to the present disclosure may be a computer-readable signal medium or a computer-readable storage medium or any combination thereof. The computer-readable storage medium may include, but is not limited to, a system, an apparatus, or a device in an electronic, magnetic, optical, electromagnetic, infrared, or semi-conductive form, or any combination thereof. More specific examples of the computer-readable storage medium may include, but are not limited to, an electrical connection with one or more wires, a portable computer disk, a hard disk, a random-access memory (RAM), a read-only memory (ROM), an erasable programmable read-only memory (EPROM or a flash memory), an optical fiber, a portable compact disc read-only memory (CD-ROM), an optical storage device, a magnetic storage device or any suitable combination thereof. In the present disclosure, the computer-readable storage medium may be any tangible medium including or storing a program, and the program may be used by or in combination with an instruction execution system, apparatus, or device. In the present disclosure, the computer-readable signal medium may include a data signal in a baseband or transmitted as a part of a carrier wave and the computer-readable signal medium stores computer-readable program codes. The propagated data signal may be in various forms, including but not limited to an electromagnetic signal, an optical signal or any suitable combination thereof. The computer-readable signal medium may alternatively be any computer-readable medium other than the computer-readable storage medium. The computer-readable signal medium may send, propagate or transmit a program for use by or use in combination with an instruction execution system, apparatus or device. The program codes stored in the computer-readable medium may be transmitted via any proper medium including but not limited to: a wire, an optical cable, radio frequency (RF) and the like, or any suitable combination thereof.

The foregoing computer-readable medium may be included in the foregoing electronic device, or may exist alone without being assembled into the electronic device.

The embodiments in this specification are described in a progressive manner. Various embodiments may refer to each other for the same or similar parts, and each embodiment places emphasis on the difference from other embodiments. The apparatus embodiments are essentially similar to the method embodiments, and therefore are described in brief. Reference may be made to the description of the method embodiments for relevant details of the apparatus embodiments.

The foregoing merely shows preferred embodiments of the present disclosure.

Although the present disclosure has been disclosed with reference to the above preferred embodiments, it is not intended to limit the present disclosure. Any person skilled in the art may, without departing from the scope of the technical solutions of the present disclosures, make various modifications and adaptations to the technical solutions based on the above disclosed method and technical solutions, or modify them to obtain equivalent embodiments that achieve the same effects. Therefore, any simple modifications, equivalent variations, and adaptations made to the above embodiments based on the technical essence of the present disclosure, without departing from the scope of the technical solutions of the present disclosure, shall still fall within the protection scope of the present disclosure.

1. A structure for surface plasmon lithography imaging, comprising:
a reflective layer arranged at a side of a to-be-etched structure;
a photoresist layer arranged at a side of the reflective layer away from the to-be-etched structure;
a first resonant cavity structure arranged at a side of the photoresist layer away from the to-be-etched structure; and
a mask layer arranged at a side of the first resonant cavity structure away from the to-be-etched structure.

2. The structure for surface plasmon lithography imaging according to claim 1, wherein
the first resonant cavity structure comprises a first multilayer structure, the first multilayer structure comprises a first metal layer and a first dielectric layer, and the first dielectric layer is arranged at a side of the first metal layer away from the to-be-etched structure.

3. The structure for surface plasmon lithography imaging according to claim 1, wherein a second resonant cavity structure is arranged between the reflective layer and the to-be-etched structure.

4. The structure for surface plasmon lithography imaging according to claim 3, wherein the second resonant cavity structure comprises at least one second multilayer structure, each of the at least one second multilayer structure comprises a second metal layer and a second dielectric layer, and the second dielectric layer is arranged at a side of the second metal layer away from the to-be-etched structure.

5. The structure for surface plasmon lithography imaging according to claim 3, wherein a thickness of the second resonant cavity structure is greater than a thickness of the first resonant cavity structure.

6. The structure for surface plasmon lithography imaging according to claim 2, wherein a thickness of the first metal layer ranges from 5 nm to 50 nm, and a thickness of the first dielectric layer ranges from 1 nm to 50 nm.

7. The structure for surface plasmon lithography imaging according to claim 1, wherein when a mask pattern of the mask layer is fixed, a pitch of a pattern formed on the to-be-etched structure during etching is regulated through regulating a thickness of the photoresist layer.

8. The structure for surface plasmon lithography imaging according to claim 1, wherein a transparent substrate is arranged at a side of the mask layer away from the to-be-etched structure.

9. A method for surface plasmon lithography imaging, comprising:
forming a reflective layer at a side of a to-be-etched structure;
forming a photoresist layer at a side of the reflective layer away from the to-be-etched structure;
forming a first resonant cavity structure at a side of the photoresist layer away from the to-be-etched structure; and
forming a mask layer at a side of the first resonant cavity structure away from the to-be-etched structure, wherein the reflective layer, the photoresist layer, the first resonant cavity structure, and the mask layer form a structure for surface plasmon lithography imaging;
illuminating the structure for surface plasmon lithography imaging in a direction from the mask layer toward the to-be-etched structure, to transfer a mask pattern of the mask layer to the photoresist layer to form a patterned photoresist layer; and
etching the to-be-etched structure by using the patterned photoresist layer.

10. A non-transitory computer-readable medium, comprising:
instructions,
wherein the instructions, when being executed on a computer, causes the computer to perform the method according to claim 9.

11. The structure for surface plasmon lithography imaging according to claim 2, wherein a transparent substrate is arranged at a side of the mask layer away from the to-be-etched structure.

12. The structure for surface plasmon lithography imaging according to claim 3, wherein a transparent substrate is arranged at a side of the mask layer away from the to-be-etched structure.

13. The structure for surface plasmon lithography imaging according to claim 4, wherein a transparent substrate is arranged at a side of the mask layer away from the to-be-etched structure.

14. The structure for surface plasmon lithography imaging according to claim 5, wherein a transparent substrate is arranged at a side of the mask layer away from the to-be-etched structure.

15. The structure for surface plasmon lithography imaging according to claim 6, wherein a transparent substrate is arranged at a side of the mask layer away from the to-be-etched structure.

16. The structure for surface plasmon lithography imaging according to claim 7, wherein a transparent substrate is arranged at a side of the mask layer away from the to-be-etched structure.
